(19) United States
(12) Patent Application Publication
(10) Pub. No.: US 2007/0086170 A1
(43) Pub. Date: Apr. 19, 2007

(54) HEAT SINK DEVICE WITH SHIELDING MEMBER

(75) Inventor: JEN-YU LIANG, TU CHENG (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., TU CHENG (TW)

(21) Appl. No.: 11/308,587

(22) Filed: Apr. 10, 2006

(30) Foreign Application Priority Data
Oct. 18, 2005 (CN) 200510100492.2

(51) Int. Cl. H05K 7/20

(52) U.S. Cl. 361/719; 165/80.3

(57) ABSTRACT

A heat sink device includes a heat sink (20) and a shielding member (30). The heat sink defines a receiving groove (220). The shielding member includes a fixing plate (322) received in the receiving groove, and a receiving portion (300) for receiving an electronic component. The heat sink device not only protects the electronic component from EMI, but also effectively dissipates heat generated by the electronic component.

### 1. FIELD OF THE INVENTION

The present invention relates to heat sinks, and particularly to a heat sink device with a shielding member that provides electromagnetic interference (EMI) shielding.

### 2. DESCRIPTION OF RELATED ART

FIG. 4 is an isometric view of a conventional heat sink 40. The heat sink 40 can be mounted on an electronic component (not shown). The heat sink 40 comprises a plurality of heat fins 42 for dissipating heat generated by the electronic component. However, the electronic component generally comprises high frequency circuits (HFC), digital signal circuits (DSC), and analog signal circuits (ASC). Electromagnetic Interference (EMI) often occurs between neighboring electronic components due to inductive coupling. In addition, the heat sink 40 does not shield the electronic component from external EMI. Therefore, the effective performance of the electronic component may be interrupted, obstructed, or degraded by EMI.

Therefore, a heretofore unaddressed need exists in the industry to overcome the aforementioned deficiencies and inadequacies.

### SUMMARY OF INVENTION

In an exemplary embodiment, a heat sink device includes a heat sink and a shielding member. The heat sink defines a receiving groove. The shielding member includes a fixing plate received in the receiving groove, and a receiving portion for receiving an electrical component. The heat sink device not only protects the electronic component from EMI, but also effectively dissipates heat generated by the electronic component.

Other advantages and novel features will become more apparent from the following detailed description when taken in conjunction with the accompanying drawings, in which:

### BRIEF DESCRIPTION OF DRAWINGS

FIG. 1 is an exploded, isometric view of a heat sink device in accordance with an exemplary embodiment of the present invention, together with a circuit board;

FIG. 2 is an assembled view of FIG. 1;

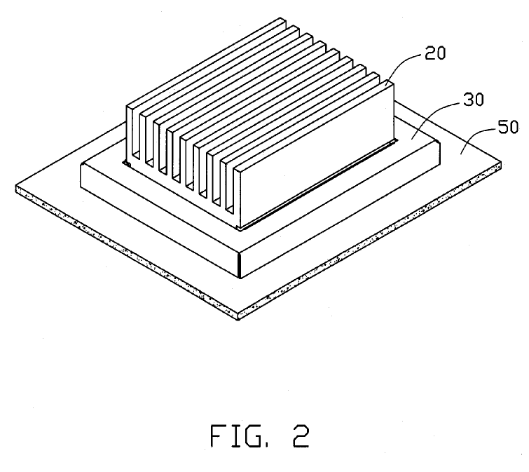

FIG. 3 is a cross-sectional view along taken line 111-111 of FIG. 2; and

FIG. 4 is an isometric view of a conventional heat sink.

### DETAILED DESCRIPTION

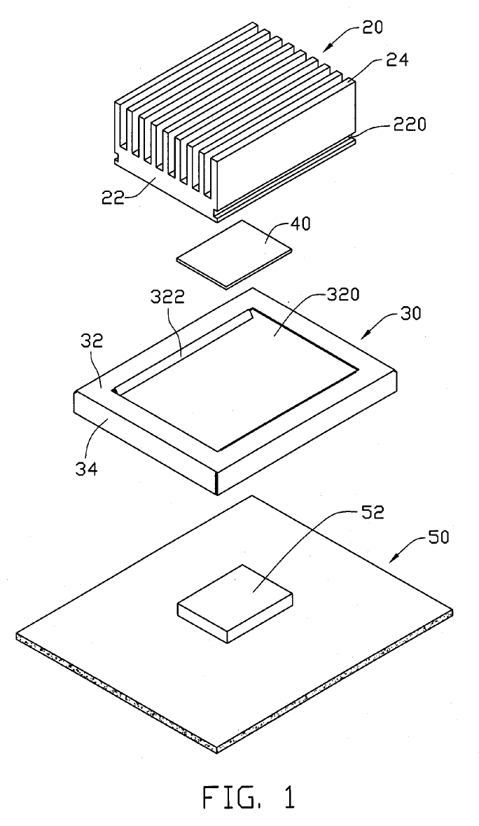

Referring to FIG. 1, a heat sink device of an exemplary embodiment of the present invention is mounted on a circuit board 50 including an electronic component 52, such as a printed circuit board. The heat sink device comprises a heat sink 20, a shielding member 30, and a heat conducting film 40.

The heat sink 20 includes a plurality of heat fins 24 and a base 22. The heat fins 24 are integrally formed with the base 22, and are perpendicular to the base 22. Two receiving grooves 220 are respectively defined in opposite sidewalls of the base 22. In an alternative embodiment, the receiving grooves 220 can be respectively defined in the two outboard heat fins 24.

The shielding member 30 is used for providing EMI shielding to the electronic component 52. The shielding member 30 comprises a top wall 32, and four sidewalls 34 each perpendicular to the top wall 32. The top wall 32 and the sidewalls 34 cooperatively surround a receiving portion 300. The electronic component 52 is received in the receiving portion 300. An opening 320 is defined in a middle of the top wall 32. A pair of fixing plates 322 is formed at opposite lengthwise sides of the opening 320.

The heat conducting film 40 is made of silicon rubber, aluminum oxide, aluminum coil, or other thermal conductive materials. The heat conducting film 40 is used for timely conducting away heat generated by the electronic component 52.

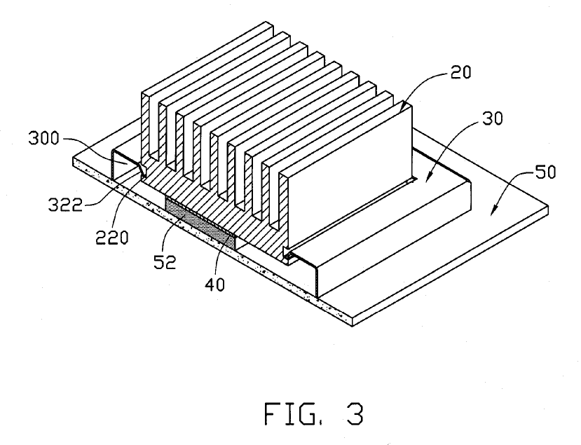

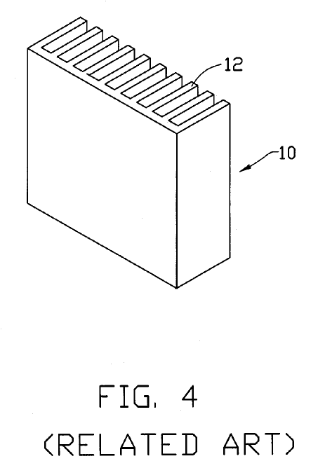

Referring to FIGS. 3 and 4, in assembly, the heat conducting film 40 is coupled to a bottom surface of the heat sink 20. One of the fixing plates 322 of the shielding member 30 is received in one corresponding receiving groove 220 of the base 20. The other fixing plate 322 is received in the other corresponding receiving groove 220 via horizontal movement of the heat sink 20. Thus, the heat sink 20, the shielding member 30, and the heat conducting film 40 are assembled. Then, the assembly of the heat sink 20, the shielding member 30, and the heat conducting film 40 is mounted on the circuit board 50 over the electronic component 52. In this assembled state, the heat conducting film 40 abuts against the electronic component 52.

In disassembly, one of the fixing plates 322 is detached from the corresponding receiving groove 220 via horizontal movement of the heat sink 20, so that the heat sink 20 is disengaged from the shielding member 30. Assembly or disassembly of the heat sink device is simple, and therefore maintenance to or replacement of the electrical component 52 is convenient.

Because the heat sink device comprises the shielding member 30 and the heat sink 20, the heat sink device is able to not only protect the electronic component 52 received in the shielding member 30 from EMI, but also effectively dissipate heat generated by the electronic component 52.

In alternative embodiments, the heat fins 24 may instead be heat pins, heat dissipating protuberances, heat plates, or other heat dissipating structures known in the art.

While exemplary embodiments have been described above, they should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A heat sink device comprising:
a heat sink defining a receiving groove; and
a shielding member comprising a fixing plate received in the receiving groove, and a receiving portion for receiving an electronic component.

2. The heat sink device as claimed in claim 1, wherein the shielding member defines an opening.

3. The heat sink device as claimed in claim 2, wherein the number of the fixing plate is two, the fixing plates respectively formed at opposite sides of the opening.

4. The heat sink device as claimed in claim 3, wherein the shielding member comprises a top wall, and a plurality of sidewalls each perpendicular to the top wall, the top wall and the sidewalls surrounding the receiving portion, the opening defined in the top wall.

5. The heat sink device as claimed in claim 1, wherein the heat sink comprises a base, and a plurality of heat dissipating protuberances perpendicular to the base.

6. The heat sink device as claimed in claim 5, wherein the number of the receiving groove is two, the receiving grooves respectively defined in opposite sides of the base.

7. The heat sink device as claimed in claim 1, further comprising a heat conducting film coupled to the heat sink.

8. The heat sink device as claimed in claim 7, wherein the heat conducting film is made of silicon rubber.

9. An electronic device assembly comprising:
a circuit board comprising an electronic component;
a heat sink for dissipating heat generated by the electronic component, the heat sink comprising a receiving groove; and
a shielding member mounted on the circuit board, the shielding member comprising a fixing plate received in the receiving groove, and a receiving portion for receiving the electrical component.

10. The electronic device assembly as claimed in claim 9, wherein the shielding member defines an opening.

11. The electronic device assembly as claimed in claim 10, wherein the number of the fixing plate is two, the fixing plates respectively formed at opposite sides of the opening.

12. The electronic device assembly as claimed in claim 11, wherein the shielding member comprises a top wall, and a plurality of sidewalls each perpendicular to the top wall, the top wall and the sidewalls surrounding the receiving portion, the opening defined in the top wall.

13. The electronic device assembly as claimed in claim 9, wherein the heat sink comprises a base, and a plurality of heat dissipating protuberances perpendicular to the base.

14. The electronic device assembly as claimed in claim 13, wherein the number of the receiving groove is two, the receiving grooves respectively defined in opposite sides of the base.

15. The electronic device assembly as claimed in claim 9, further comprising a heat conducting film coupled to the heat sink.

16. The electronic device assembly as claimed in claim 15, wherein the heat conducting film is made of silicon rubber.
